(19) United States
(12) Patent Application Publication
(10) Pub. No.: US 2012/0211786 A1
(43) Pub. Date: Aug. 23, 2012

(54) LED PACKAGE STRUCTURE WITH A WIDE OPTICAL FIELD

(75) Inventors: Hsin-Chiang LIN, Hukou (TW); Wen-Liang TSENG, Hukou (TW); Pin-Chuan CHEN, Hukou (TW)

(73) Assignee: ADVANCED OPTOELECTRONIC TECHNOLOGY, INC., Hsinchu Hsien (TW)

(21) Appl. No.: 13/278,113

(22) Filed: Oct. 20, 2011

(30) Foreign Application Priority Data
Feb. 17, 2011 (CN) 201110041287.9

(51) Int. Cl. H01L 33/52

(52) U.S. Cl. 257/98; 257/E33.059

(57) ABSTRACT

An LED package structure with a wide optical field comprises a substrate, an LED chip, and an encapsulation. The substrate has at least two electrodes and a carrier. The carrier has a carrier surface. The carrier surface is higher than a top surface of the substrate and higher than the electrodes. The LED chip is mounted on the carrier surface. The LED chip electrically connects with the electrodes via wires. The encapsulation covers the LED chip. The LED chip has a wide light emitting angle.

### BACKGROUND

1. Technical Field

The disclosure relates to light emitting diodes, and particularly to an LED package structure with a wide optical field.

2. Description of the Related Art

Light emitting diodes' (LEDs) have many advantages, such as high luminosity, low operational voltage, low power consumption, compatibility with integrated circuits, faster switching, long term reliability, and environmental friendliness which have promoted their wide use as a light source. Now, light emitting diodes are commonly applied in environmental lighting.

Only half of light from an active layer of common LEDs can pass through a surface of the common LEDs. The remaining is absorbed by an LED package structure. Therefore, increasing light extraction efficiency is an important issue. Furthermore, the illumination of the common LEDs has a relatively small optical filed (i.e., illumination angle), whereby a uniform illumination cannot obtained, which is required in some applications.

Therefore, it is desirable to provide an LED package structure with a wide optical field and a better light extraction efficiency which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present LED package structure with a wide optical field. Moreover, in the drawings, like reference numerals designate corresponding parts throughout the views.

FIG. 1 is a cross sectional view of an LED package structure in accordance with a first embodiment.

FIG. 2 is a cross sectional view of an LED chip and a carrier of the LED package structure of FIG. 1.

FIG. 3 is an enlarged drawing of a portion of the LED chip and the carrier of FIG. 2.

FIG. 4 is a cross sectional view of an LED package structure in accordance with a second embodiment.

FIG. 5 is a cross sectional view of an LED package structure in accordance with a third embodiment.

### DETAILED DESCRIPTION

Embodiments of an LED package structure with a wide optical field as disclosed are described in detail here with reference to the drawings.

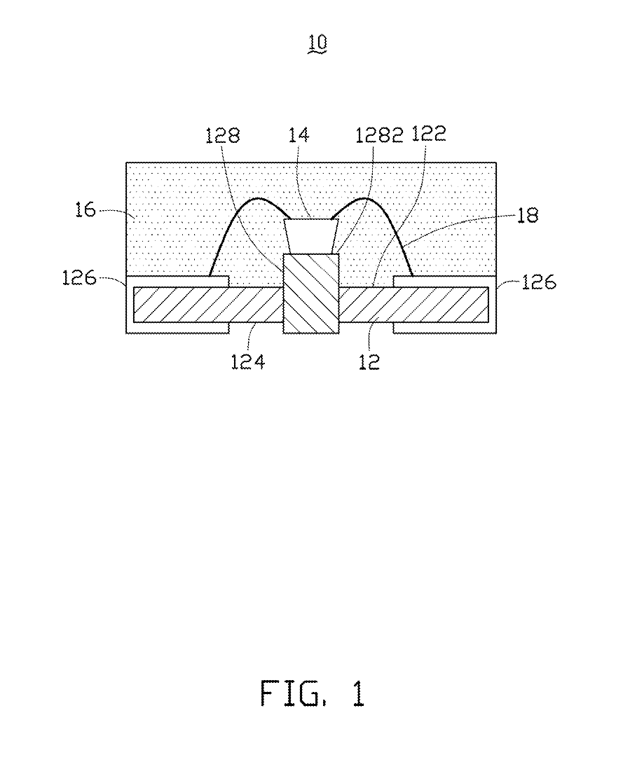

Referring to FIG. 1, an LED package structure with a wide optical field 10 in accordance with a first embodiment includes a substrate 12, an LED chip 14, and an encapsulation 16. The substrate 12 includes a top surface 122, a bottom surface 124, at least two electrodes 126, and a carrier 128. The two electrodes 126 and the carrier 128 extend from the top surface 122 to the bottom surface 124 of substrate 12. The carrier 128 has a carrier surface 1282. The carrier surface 1282 is higher than the top surface 122 of the substrate 12 and higher than the two electrodes 126. The carrier surface 1282 is corresponding to the LED chip 14. The LED chip 14 is mounted on the carrier surface 1282. The LED chip 14 electrically connects with the electrodes 126 via conductive wires 18, and the encapsulation 16 covers the LED chip 14, the wires 18, the top surface 122, portions of the electrodes 126 on the top surface 122 and a portion of the carrier 128 above the top surface 122.

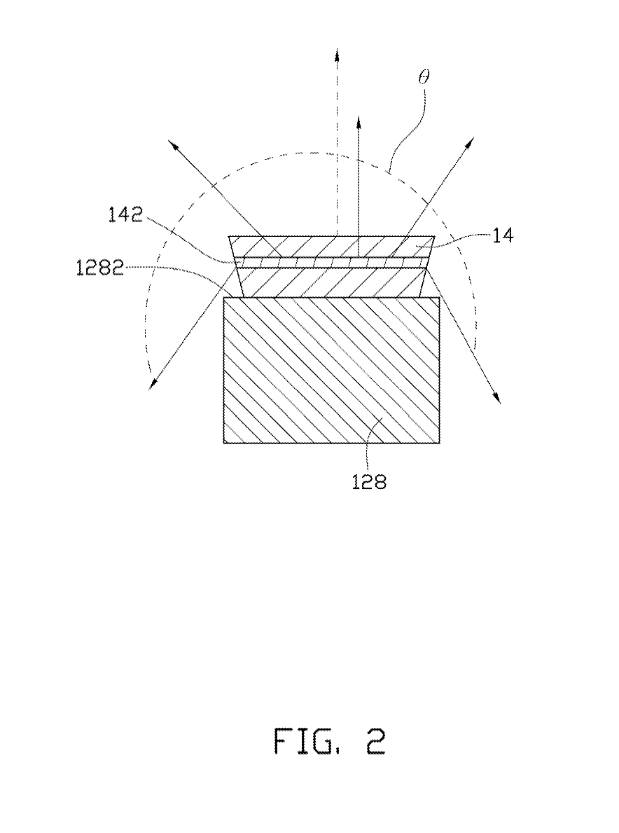

The encapsulation 16 is a transparent material, and includes a plurality of phosphor powder. The LED chip 14 is on the carrier surface 1282. A certain distance is between the top surface 122 of the substrate 12 and the LED chip 14. Thus, light from the LED chip 14 with an emitting angle θ is not blocked by the substrate 12. The LED chip 14 has a wide light emitting angle. Referring to FIG. 2, the emitting angle θ of the LED chip 14 is about 240°. The emitting angle θ of the LED chip 14 is according to a relative position of the LED chip 14 and the carrier surface 1282 of the carrier 128.

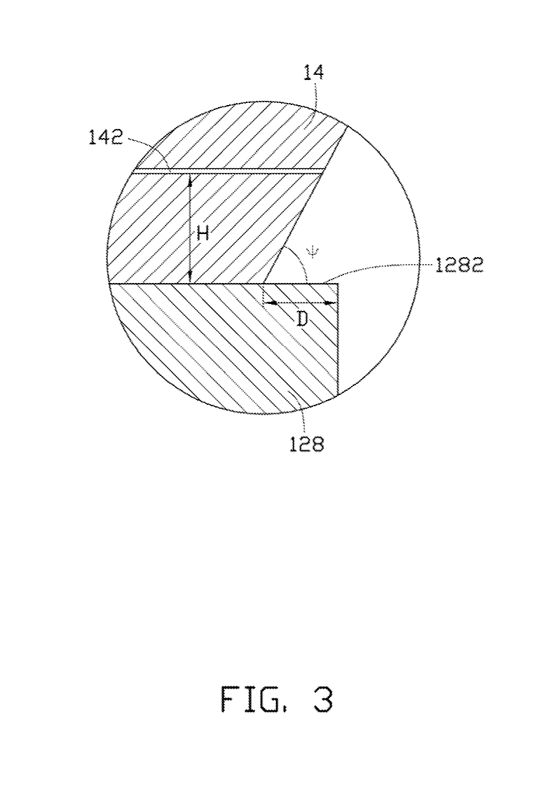

The equation about the relative position of the LED chip 14 and the carrier surface 1282 of the carrier 128 is tan ψ≦H/D, wherein ψ is an included angle between an inclined lateral side of the LED chip 14 and the carrier surface 1282 of the carrier 128. H is a height from an active layer 142 of the LED chip 14 to a bottom surface of the LED chip 14. D is a distance between a side of the bottom surface of the LED chip 14 and a corresponding lateral side of the carrier 128 (as shown in FIG. 3). The light emitting angle θ of the LED chip 14 is expanded. Thus, an optical field of the LED chip 14 is expanded, and a brightness of the LED package structure with a wide optical field 10 increases.

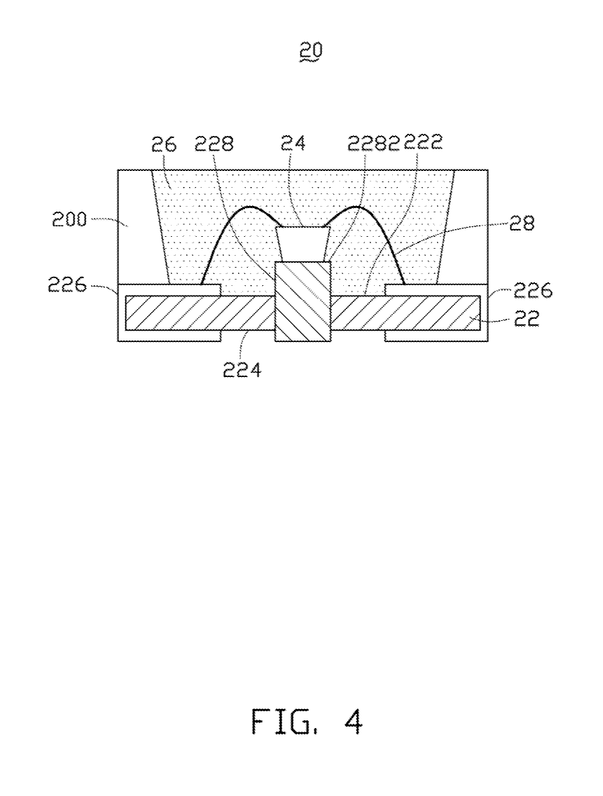

Referring to FIG. 4, an LED package structure with a wide optical field 20 in accordance with a second embodiment includes a substrate 22, an LED chip 24, and an encapsulation 26. The substrate 22 includes a top surface 222, a bottom surface 224, at least two electrodes 226, and a carrier 228. The carrier 228 includes a carrier surface 2282; the carrier surface 2282 is higher than the top surface 222 of the substrate 22 and higher than the electrodes 226, and the LED chip 24 is arranged on the carrier surface 2282 of the carrier 228. The LED chip 24 electrically connects with the electrodes 226 via conductive wires 28. The encapsulation 26 covers the LED chip 24, the wires 28, the top surface 222, portions of the electrodes 126 on the top surface 222 and a portion of the carrier 228 above the top surface 222.

The only difference is that the top surface 222 of the substrate 22 has a refection cup 200. The reflection cup 200 surrounds the LED chip 24. Light from the LED chip 24 with a wide optical field is reflected by the reflection cup 200 and emits from an opening of the refection cup 200. That enhances the brightness of the LED package structure with a wide optical field 20.

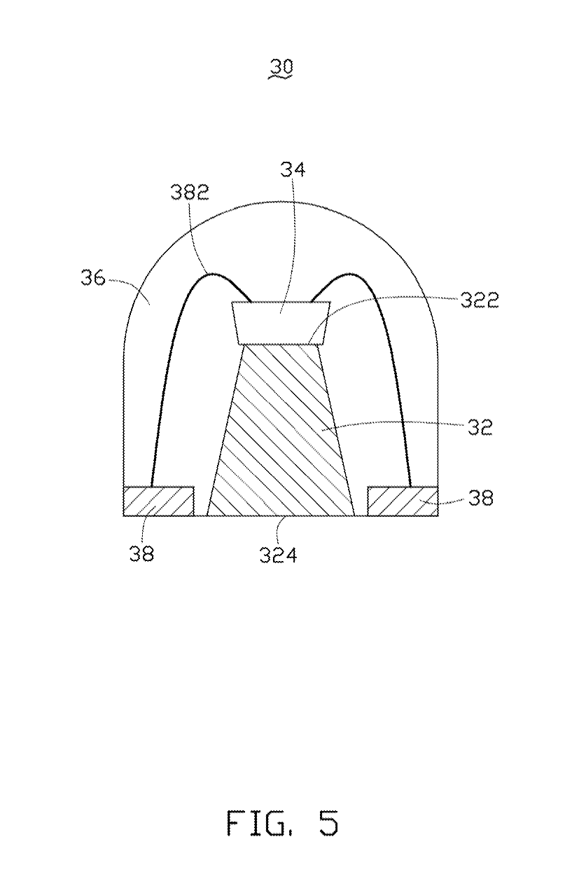

Referring to FIG. 5, an LED package structure with a wide optical field 30 in a third embodiment includes a carrier 32, an LED chip 34, an encapsulation 36, and two electrodes 38. The carrier 32 is higher than the electrodes 38. The only difference from the LED package structure with a wide optical field 10 of the first embodiment, the LED package with a wide optical field 30 of the third embodiment does not include the substrate 12. The carrier 32 has a carrier surface 322 and a bottom surface 324. A certain distance is between the carrier surface 322 and the bottom surface 324. The bottom surface 324 is coplanar with bottom surfaces (not labeled) of the electrodes 38. The carrier 32 has a certain height. The carrier surface 322 is corresponding to the LED chip 34. The LED chip 34 is mounted on the carrier surface 322. The LED chip 34 electrically connects with the electrodes 38 via conductive wires 382. The encapsulation 36 encapsulates the LED chip 34, the wires 382, the electrodes 38, and the carrier 32. The LED package structure with a wide optical field 30 can be directly mounted on a printed circuit board.

In a further alternative embodiment, which is not shown here, the carrier 32 can be arranged on one of the electrodes 38, which is extended to support the bottom surface 324 of the carrier 32.

The LED chips 14, 24, and 34 are arranged on the carrier surfaces 1282, 2282, and 322 of the carrier 128, 228, and 32. The position of the LED chips 14, 24, and 34 in the LED package structure with a wide optical field 10, 20, and 30 is raised. The light emitting angle θ is expanded and the light extraction efficiency is improved.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An LED package structure with a wide optical field, comprising: a substrate, an LED chip having an inclined lateral side, and an encapsulation, the substrate including at least two electrodes, and a carrier, the carrier having a carrier surface, the carrier surface being higher than the substrate and higher than the at least two electrodes, the LED chip being arranged on the carrier surface, the LED chip electrically connected with the electrodes via conductive wires, and the encapsulation covering the LED chip.

2. The LED package structure with a wide optical field of claim 1, wherein the substrate includes a top surface, a bottom surface, the two electrodes, and the carrier extend from the top surface to the bottom surface of the substrate.

3. The LED package structure with a wide optical field of claim 1, wherein an equation about relative positions of the LED chip and the carrier surface of the carrier is satisfied: tan ψ≦H/D, wherein ψ is an included angle between the inclined lateral side of the LED chip and the carrier surface of the carrier, H is a height from an active layer of the LED chip to a bottom surface of the LED chip, and D is a distance between a side of the bottom surface of the LED chip and a lateral side of the carrier.

4. The LED package structure with a wide optical field of claim 3, wherein an emitting angle θ of the LED chip is 240°.

5. The LED package structure with a wide optical field of claim 1, wherein the substrate has a refection cup thereon, and the reflection cup surrounds the LED chip.

6. The LED package structure with a wide optical field of claim 1, wherein the encapsulation is a transparent material, and includes a plurality of phosphor powder.

7. An LED package structure with a wide optical field, comprising: an LED chip, an encapsulation, and at least two electrodes, the carrier including a carrier surface, the LED chip being arranged on the carrier surface, the LED chip electrically connected with the electrodes via wires, and the encapsulation covering the LED chip, the carrier, the wires and the electrodes, the carrier being higher than the at least two electrodes.

8. The LED package structure with a wide optical field of claim 7, wherein the carrier has a bottom surface the bottom surface being coplanar with bottom surfaces of the at least two electrodes.

9. The LED package structure with a wide optical field of claim 7, wherein the carrier is arranged at one of the electrodes.
